(19) United States
(12) Patent Application Publication
(10) Pub. No.: US 2015/0309107 A1
(43) Pub. Date: Oct. 29, 2015

(54) METHOD AND SYSTEM FOR DETECTING HEALTH OF WINDINGS FOR ELECTROMAGNETIC DEVICES

(71) Applicant: AUTOMATIC SWITCH COMPANY, Florham Park, NJ (US)

(72) Inventor: Stanley B. ROEDEL, Budd Lake, NJ (US)

(73) Assignee: AUTOMATIC SWITCH COMPANY, Florham Park, NJ (US)

(21) Appl. No.: 14/261,210

(22) Filed: Apr. 24, 2014

(51) Int. Cl. G01R 31/06

(52) U.S. Cl. CPC G01R 31/06

(57) ABSTRACT

The present disclosure provides a method and system for measuring an increase in wattage to detect a potential winding failure. The increase in watts in the winding occurs when a time-varying magnetic field from active turns of the winding induces a time-varying current on shorted turns of the winding. The resistance through the shorted turns and the induced current result in power usage and increased watts. The wattage increase is much greater than a resistance decrease in the winding by the shorted turns. Measuring the watts results in detecting a shorting winding with greater sensitivity than measuring the resistance. In one embodiment, the winding can be tested offline with a wattmeter and power supply. In another embodiment, the winding in use and its wattage can be monitored continuously or periodically locally or remotely, with an optional sensor to initiate a signal upon reaching a certain percentage increase in watts.

### CROSS REFERENCE TO RELATED APPLICATIONS

Not applicable.

### STATEMENT REGARDING FEDERALLY SPONSORED RESEARCH OR DEVELOPMENT

Not applicable.

### REFERENCE TO APPENDIX

Not applicable.

### BACKGROUND OF THE INVENTION

1. Field of the Invention

The disclosure generally relates to electrical windings. More specifically, the disclosure relates to the detection of degradation of electrical windings for electromagnetic devices, such as solenoid coils, inductors, electromagnets, transformers, sensor coils, motors, and generators.

2. Description of the Related Art

An electromagnetic device typically includes an electrical winding. The winding is made of an electrical conductor such as a wire typically in the shape of a coil, such as a spiral or helix, to form a continuous series of winding turns.

Windings for the electromagnetic devices have an insulation layer of some type around the windings. The insulation is typically thin to allow for the close packing of the winding turns. The insulation can be a material with insulating properties that gradually degrade from various service conditions. As the winding insulation degrades, it eventually allows local exposure of the underlying conductor. If the insulation of the adjacent winding turns is intact, no shorting of turns occurs. However, if two or more exposed winding turns are adjacent to one another, the winding turns between the adjacent exposed conductors are shorted. Shorting of turns is progressive, eventually leading to winding failure.

Windings for electromagnetic devices, such as solenoids in solenoid-operated valves, are often scheduled for replacement at intervals far less than the average winding life, so that unexpected winding failures are reduced. Having knowledge of the health of the winding in an electromagnetic device is desirable to reduce both premature replacement and unexpected winding failures, each of which results in downtime of the process of which the electromagnetic device is a part. Windings in other electromagnetic devices are similarly situated. Thus, the principles apply to other applications using windings.

Some known systems disclose monitoring a solenoid health, such as U.S. Pat. No. 8,055,460. This patent discloses a method for monitoring the state of health (SOH) of a solenoid powered by a battery and includes measuring a voltage and a current supplied to the solenoid by the battery, using a processor to determine each of an equivalent resistance and inductance of the solenoid using the voltage and the current, comparing the equivalent resistance and the equivalent inductance to a corresponding calibrated threshold, and recording deviations from the corresponding calibrated thresholds as a pair of SOH values. A trend of the SOH values is continuously monitored, and an appropriate control action is taken when either SOH value drops below a calibrated lower limit. A solenoid monitoring system includes a solenoid, voltage and current sensors, and a controller having an algorithm for continuously monitoring a state of health of the solenoid. In general, U.S. Pat. No. 8,055,460 teaches measuring voltage from a battery supplying power to the circuit, a current, and resistance in the circuit together with a time constant, to calculate an equivalent inductance and equivalent resistance in the circuit. These calculated values can be compared with a known “good” solenoid having a nominal or calibrated value for inductance and resistance as reference values to indicate the condition of the solenoid in question, and apparent cause of a failure such as an open circuit or a shorted winding turn in the solenoid.

However, the inventors of the present disclosure have realized that measuring voltage, resistance, or current parameters and mapping changes does not yield sufficient sensitivity to determine a failing electrical winding. Therefore, despite some efforts in the field, such as those found in the above exemplary US patent, for determining a failing electrical winding, there remains then a need for improved detection of the health of a winding.

### BRIEF SUMMARY OF THE INVENTION

The present disclosure provides a method and system for measuring an increase in wattage to detect a potential winding failure. The increase in watts in the winding occurs when a time-varying magnetic field from active turns of the winding induces a time-varying current on shorted turns of the winding. The resistance through the shorted turns and the induced current result in power usage and increased watts. The wattage increase is much greater than a resistance decrease in the winding by the shorted turns. Measuring the watts results in detecting a shorting winding with greater sensitivity than measuring the resistance. In one embodiment, the winding can be tested offline with a wattmeter and power supply. In another embodiment, the winding in use and its wattage can be monitored continuously or periodically locally or remotely, with an optional sensor to initiate a signal upon reaching a certain percentage increase in watts.

The disclosure provides a method of measuring the health of an electrical winding for an electromagnetic device, the method comprising: applying a time-varying voltage to an electrical winding having a plurality of winding turns; measuring a wattage of the winding; comparing the measured wattage of the winding to a predetermined reference wattage for the winding; and determining if the measured wattage is greater than the reference wattage to indicate one or more shorted winding turns in the winding. The method further provides wherein the one or more shorted winding turns creates an induced current, and wherein measuring the wattage comprises measuring the wattage of the induced current of the shorted winding turns.

The disclosure provides a system for measuring the health of an electrical winding, comprising: an electrical winding having a plurality of winding turns; a power supply coupled to the winding for providing a time-varying voltage to the winding; and a wattmeter coupled to the winding. The present invention further provides wherein a shorted winding turn creates an induced current in the winding and wherein the wattmeter measures a wattage, including wattage from the induced current, for reference to a reference wattage for the winding, the reference wattage being for an electrical winding in a predetermined condition.

### BRIEF DESCRIPTION OF THE SEVERAL VIEWS OF THE DRAWINGS

FIG. 1A is a schematic diagram of a system of an electrical winding of an exemplary electromagnetic device, such as a solenoid coil, with a wattmeter to measure the wattage of the winding.

FIG. 1B is a schematic diagram of a system of an electrical winding of another exemplary electromagnetic device, such as a motor or a generator, with a wattmeter to measure the wattage of the winding.

FIG. 2 is a schematic diagram of an electrical winding with turns having a portion of active turns and a portion of shorted turns that are magnetically coupled with the active turns.

FIG. 3 is a graph of exemplary percentage changes in current compared with wattage for a given percentage of shorted turns of the total turns.

FIG. 4 is a schematic diagram of a system with an electrical winding, wattmeter, time-varying power supply, controller, monitor, and apparatus.

FIG. 5 is a schematic diagram of a system with an electrical winding, direct current power supply, controller, and a superimposed time-varying signal from a time-varying power supply and a wattmeter.

### DETAILED DESCRIPTION

The Figures described above and the written description of specific structures and functions below are not presented to limit the scope of what Applicant has invented or the scope of the appended claims. Rather, the Figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present disclosure will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of ordinary skill in this art having benefit of this disclosure. It must be understood that the inventions disclosed and taught herein are susceptible to numerous and various modifications and alternative forms. The use of a singular term, such as, but not limited to, “a,” is not intended as limiting of the number of items. Also, the use of relational terms, such as, but not limited to, “top,” “bottom,” “left,” “right,” “upper,” “lower,” “down,” “up,” “side,” and the like are used in the written description for clarity in specific reference to the Figures and are not intended to limit the scope of the invention or the appended claims. Where appropriate, one or more elements may have been labeled with an “A” or “B” to designate various members of a given class of an element. When referring generally to such elements, the number without the letter is used. Further, such designations do not limit the number of members that can be used for that function.

The present disclosure provides a method and system for measuring an increase in wattage to detect a potential winding failure. The increase in watts in the winding occurs when a time-varying magnetic field from active turns of the winding induces a time-varying current on shorted turns of the winding. The resistance through the shorted turns and the induced current result in power usage and increased watts. The wattage increase is much greater than a resistance decrease in the winding by the shorted turns. Measuring the watts results in detecting a shorting winding with greater sensitivity than measuring the resistance. In one embodiment, the winding can be tested offline with a wattmeter and power supply. In another embodiment, the winding in use and its wattage can be monitored continuously or periodically locally or remotely, with an optional sensor to initiate a signal upon reaching a certain percentage increase in watts.

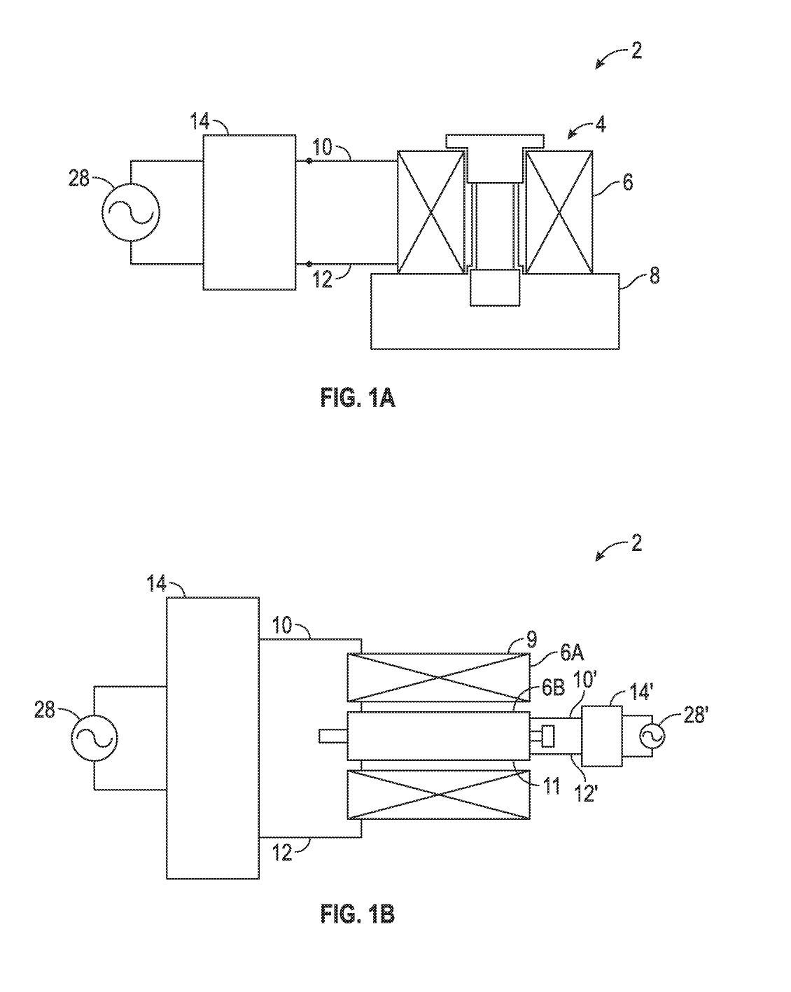

FIG. 1A is a schematic diagram of a system of an electrical winding of an exemplary electromagnetic device, such as a solenoid coil, with a wattmeter to measure the wattage of the winding. A system 2 includes an electrical winding 6 such as might be included with a solenoid 4. Typically, the solenoid 4 with its electrical winding is attached to equipment, such as a valve 8 or other equipment that interfaces with the solenoid 4 for operation. For clarification, the exemplary embodiment is not limited to solenoids and valves, but can be used with transformers and other electromagnetic devices that use windings. The winding includes a lead 10 and a lead 12. The leads are connected to a wattmeter 14. The winding would be considered in this embodiment as offline. A power supply 28 can provide power to the circuit winding. The wattmeter can measure the winding offline and determine its wattage draw. An evaluation can be made against an electrical winding in known good operating condition or some predetermined standard as a datum for comparative results. If the wattage from the electromagnetic device is more than the datum, then the electrical winding may have shorted turns and be inclined toward failure. A decision can be made to replace the winding at the present time or wait.

FIG. 1B is a schematic diagram of a system of an electrical winding of another exemplary electromagnetic device, such as a motor or a generator, with a wattmeter to measure the wattage of the winding. The system 2 includes a winding 6A for a stator 9 and a winding 6B for a rotor 11. The term “lead” is used broadly herein, and includes an accessible electrical connection of a component. The stator 9 can include a lead 10 and a lead 12 that can be connected to a wattmeter 14. A power supply 28 can provide power to the circuit winding 6A. Similarly, a rotor 11 can include leads 10′ and 12′ that can be connected to a wattmeter 14′. A power supply 28′ can provide power to the circuit winding 6B. One or both of the windings can be measured for wattage.

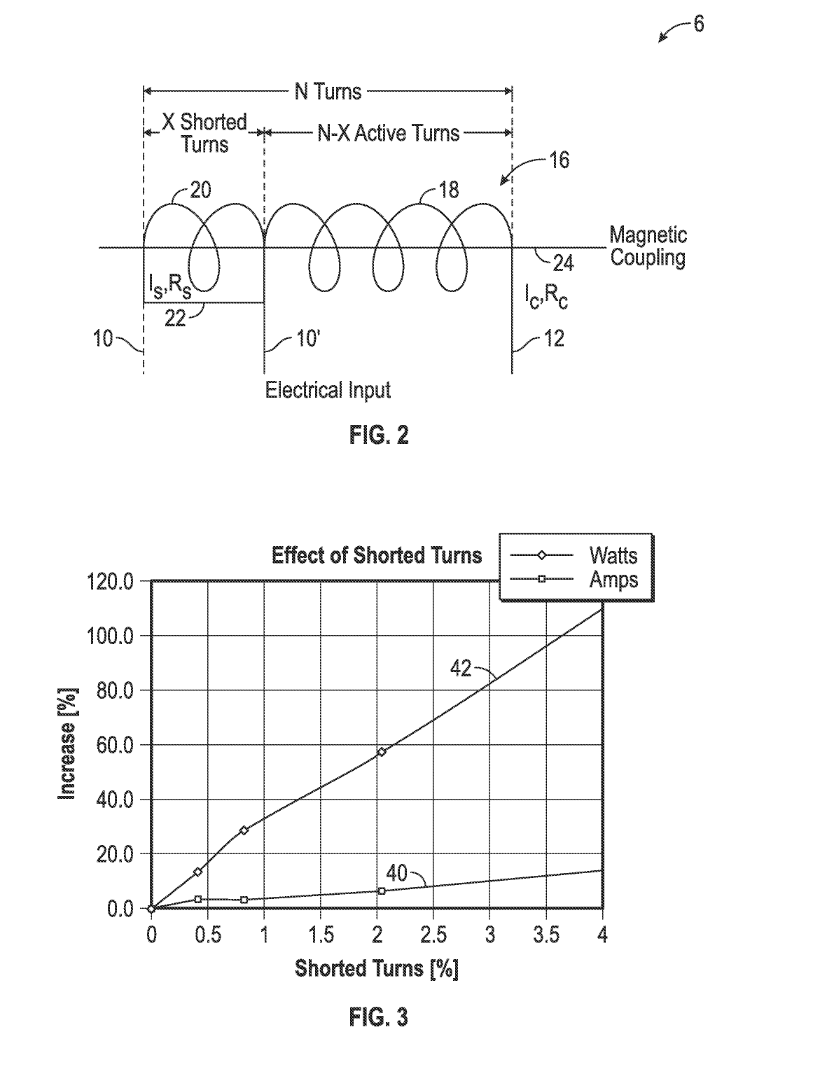

FIG. 2 is a schematic diagram of an electrical winding with turns having a portion of active turns and portion of shorted turns that are magnetically coupled with the active turns. In general, an electrical winding 6 includes a series of turns 16 of wire that surround an internal magnetic core 24. A lead 10 and a lead 12 allow current to flow into the winding through the turns and out the winding. The winding has a resistance R_{C} through which the current I_{C} flows. When a portion of the turns 16 become shorted, the resistance R_{C} decreases and the shorted turns 20 are no longer effective at their intended function. The short 22 illustrates this shorting graphically across the shorted turns 20. Effectively, the lead 10 moves to a new electrical position in the winding of lead 10′ for the remaining active turns 18. However, the shorted turns 20 consume energy caused by the induced current Is through the short and the associated shorted turns with the associated resistance Rs. When subjected to a time-varying voltage, such as an AC voltage with an associated current, the active turns 18 impart a time-varying magnetic field that produces a time-varying voltage on the shorted turns 20. An induced current I_{S} in the shorted turns 20 occurs by the time-varying current flowing through the active turns 18 that are magnetically coupled to the shorted turns 20. The active turns 18 can be considered a primary circuit of a transformer, and the shorted turns 20 can be considered a secondary circuit that is influenced by the primary circuit.

Measurement of the wattage between the lead 10 (at the effective position of lead 10′) and 12 can schematically be considered the sum of the winding current I_{C} through the winding resistance Rc and the induced current I_{S} through the shorted turns resistance Rs. The shorted turns 20 result in a measurable additional wattage at a much higher rate than the reduction in resistance in R_{C} to account for the resistance R_{S} of the shorted turns. Thus, monitoring wattage can be effectively used to detect small numbers of shorted turns, thereby allowing an improved prediction of a future failure of an electrical winding. As described in FIG. 5 below, for a direct current circuit with an electrical winding, a time-varying signal can be applied offline or superimposed over the direct current to induce a time-varying current in the shorted turns. An electrical time-varying voltage circuit incorporated in the winding, or external to it, can supply the signal. Thus, the invention to be used with either time-varying or direct current winding applications.

FIG. 3 is a graph of exemplary percentage changes in current compared with wattage for a given percentage of shorted turns of the total turns of an electrical winding. The X-axis is an increasing percentage of shorted turns in comparison to the full number of turns 16 illustrated in FIG. 2. The Y-axis is the increase in current for line 40 or watts for line 42. With 0% shorted turns, both lines by definition have a 0% increase in amps or watts. At about 2% shorted turns, the increase of amps is approximately 8%. However, the increase in watts almost 60%. At a 4% shorted turns, the increase in amps is approximately 15%, whereas the increase in watts is approximately 110%. Thus, the significant rise in watts compared to amps provides a much higher sensitivity to the effect of any increase in the number of shorted turns.

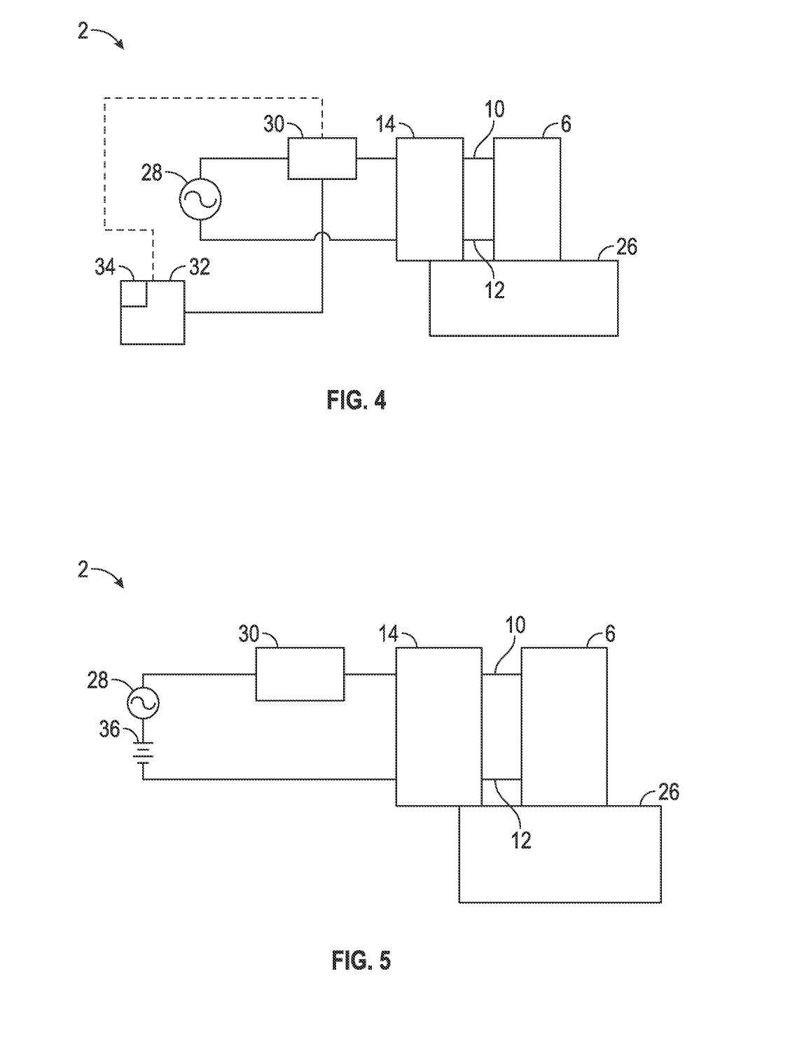

FIG. 4 is a schematic diagram of a system with an electrical winding, wattmeter, time-varying power supply, controller, monitor, and apparatus. The system includes an electrical winding 6 with leads 10 and 12 that is coupled to an apparatus 26, such as a valve, transformer, motor or generator, or other electromagnetic device as might use an electrical winding. A wattmeter 14 measures the performance and health of the winding 6. A time-varying power supply 28 provides power to the winding 6 for its intended purpose in association with the apparatus 26. A controller 30 can be used to control the performance of the power supply 28 for the winding 6. During the operation, the wattmeter 14 can be used to monitor the condition of the winding 6. The output from the wattmeter 14 can be sent to a monitor 32. The monitor 32 can include a visual display containing either digital or analog output, indicators, such as blinking lights or audible alarms, and other metrics and indicators known to those with ordinary skill in the art. An optional sensor 34 can be used to trigger alarms or other notices if the wattage increases beyond a desired level, such as a certain percentage increase in wattage compared to a normal healthy winding. The monitor 32 can be local, or even attached to the winding 6. Alternatively, the monitor 32 can be in a remote facility, such that the interface between the wattmeter 14 and the monitor 32 occurs over the Internet through a TCP/IP or other connection, or through a wireless transmission. The monitor 32 can be used to provide input to the controller 30 for operation of the power supply.

FIG. 5 is a schematic diagram of a system with an electrical winding, direct current (“DC”) power supply, controller, and a superimposed time-varying signal from a time-varying power supply and a wattmeter. FIG. 5 can include one or more aspects of the circuit of FIG. 4, except that the power supply can be a DC power supply 36. A typical DC current from the DC power supply 36 does not induce a current through the shorted turns 20, described above and illustrated in FIG. 2 because it is not a time-varying signal. Thus, a separate time-varying signal can be superimposed onto the DC circuit to induce a current in the shorted turns. A wattmeter 14 and a time-varying power supply 28 can be coupled to the leads 10 and 12 to superimpose the time-varying signal onto a DC signal from the DC power supply 36. While not shown, the wattmeter 14 can provide input to the monitor 32 and optional sensor 34 and the monitor 32 can provide input to the controller 30, as described in FIG. 4.

In operation, the wattmeter can be attached to the electrical winding to measure its condition. A power supply directly or through the wattmeter can provide current to the winding. It is envisioned that a standard winding will have a predetermined acceptable wattage as reference wattage. Any future measurements of similar windings can be compared with the reference wattage. When the winding is removed from operation for a health test, any increase in the wattage can indicate a degradation of the insulation, one or more shorted turns, and the increased potential for winding failure. Alternatively, the winding can remain in operation and a wattmeter be used to measure the condition of the winding turns during operation. Thus, a decision can be made on replacement of the winding prior to its expected approaching failure. Periodic or continuous monitoring of the health of the winding can be used to indicate when an electrical winding is approaching the end of its useful life and needs replacement. For DC circuits operating the winding, a time-varying signal can be imposed when the winding is offline, or superimposed over the DC signal so that a wattmeter can measure the wattage including wattage from an induced current in the shorted turns from the superimposed time-varying signal. The wattage can be monitored and sensed for certain threshold levels.

The various methods and embodiments of the system can be included in combination with each other to produce variations of the disclosed methods and embodiments. Discussion of singular elements can include plural elements and vice-versa. References to at least one item followed by a reference to the item may include one or more items. Also, various aspects of the embodiments could be used in conjunction with each other to accomplish the understood goals of the disclosure. Unless the context requires otherwise, the word “comprise” or variations such as “comprises” or “comprising,” should be understood to imply the inclusion of at least the stated element or step or group of elements or steps or equivalents thereof, and not the exclusion of a greater numerical quantity or any other element or step or group of elements or steps or equivalents thereof. The device or system may be used in a number of directions and orientations. The term “coupled,” “coupling,” “coupler,” and like terms are used broadly herein and may include any method or device for securing, binding, bonding, fastening, attaching, joining, inserting therein, forming thereon or therein, communicating, or otherwise associating, for example, mechanically, magnetically, electrically, chemically, operably, directly or indirectly with intermediate elements, one or more pieces of members together and may further include without limitation integrally forming one functional member with another in a unity fashion. The coupling may occur in any direction, including rotationally.

The order of steps can occur in a variety of sequences, unless otherwise specifically limited. The various steps described herein can be combined with other steps, interlineated with the stated steps, and/or split into multiple steps. Similarly, elements have been described functionally and can be embodied as separate components or can be combined into components having multiple functions.

The invention has been described in the context of preferred and other embodiments and not every embodiment of the invention has been described. Obvious modifications and alterations to the described embodiments are available to those of ordinary skill in the art. The disclosed and undisclosed embodiments are not intended to limit or restrict the scope or applicability of the invention conceived of by the Applicant, but rather, in conformity with the patent laws, Applicant intends to protect fully all such modifications and improvements that come within the scope or range of equivalent of the following claims.

What is claimed is:

1. A method of measuring the health of an electrical winding for an electromagnetic device, the method comprising:
applying a time-varying voltage to an electrical winding having a plurality of winding turns;
measuring a wattage of the winding;
comparing the measured wattage of the winding to a reference wattage for the winding, the reference wattage being for an electrical winding in a predetermined condition; and
determining if the measured wattage is different than the reference wattage to indicate one or more shorted winding turns in the winding.

2. The method of claim 1, wherein the one or more shorted winding turns creates an induced current, and wherein measuring the wattage comprises measuring the wattage including the induced current of the shorted winding turns.

3. The method of claim 1, wherein the time-varying voltage actuates a solenoid coupled to the winding.

4. The method of claim 1, further comprising applying a direct current to the winding and the step of applying a time-varying voltage comprises superimposing the time-varying voltage onto the direct current.

5. The method of claim 1, further comprising monitoring wattage from the winding during operation of the winding.

6. The method of claim 5, further comprising sensing when the wattage differs by a predetermined amount from the reference wattage.

7. The method of claim 1, wherein the electromagnetic device comprises at least one of a solenoid, a valve, transformer, a motor, and a generator.

8. A system for measuring the health of an electrical winding for an electromagnetic device, comprising:
an electrical winding having a plurality of winding turns;
a power supply coupled to the winding for providing a time-varying voltage to the winding; and
a wattmeter coupled to the winding,
wherein a shorted winding turn creates an induced current in the winding and wherein the wattmeter measures a wattage, including wattage from the induced current, for reference to a reference wattage for the winding, the reference wattage being for an electrical winding in a predetermined condition.

9. The system of claim 8, wherein the electromagnetic device comprises at least one of a solenoid, a valve, transformer, a motor, and a generator.

10. The system of claim 8, further comprising a power supply configured to apply direct current to the winding and the power supply coupled to the winding for providing a time-varying voltage to the winding is configured to superimpose the time-varying voltage onto the direct current.

11. The system of claim 8, further comprising a monitor configured to monitor wattage from the winding during operation of the winding.

12. The system of claim 11, further comprising a sensor configured to sense wattage from the winding and provide a signal when the wattage differs by a predetermined amount from the reference wattage.
